(19) United States
(12) Patent Application Publication
(10) Pub. No.: US 2007/0247347 A1
(43) Pub. Date: Oct. 25, 2007

(54) Electronic Circuit Device

(76) Inventors: Hirofumi Matsui, Kashiba-shi (JP); Kunihiko Iiizuka, Sakai-shi (JP)

Correspondence Address: BIRCH STEWART KOLASCH & BIRCH, PO BOX 747, FALLS CHURCH, VA, 22040-0747, US

(21) Appl. No.: 11/628,971

(22) PCT Filed: Jun. 6, 2005
(86) PCT No.: PCT/JP05/10362

§ 371 Date: Dec. 8, 2006

(30) Foreign Application Priority Data
Jun. 11, 2004 (JP) 2004-175581
Apr. 26, 2005 (JP) 2005-128499

(51) Int. Cl. H03M 1/12

(52) U.S. Cl. 341/155

(57) ABSTRACT

A circuit (1a) having analog circuits processes an analog input signal (Vin). The circuit (1a) having the analog circuits sends a coefficient s1 to a coefficient detection/control circuit (1b). The coefficient s1 indicates a predetermined property of each of the analog circuits provided in the circuit (1a). The coefficient detection/control circuit (1b) processes and detects the coefficient s1 as a signal value so as to detect the property of the analog circuit. The coefficient detection/control circuit (1b) sends a control signal s2, which is obtained according to a result of the detection of the coefficient s1, to the circuit (1a) having the analog circuit. In this way, the coefficient detection/control circuit (1b) adjusts an operation condition of the analog circuit so as to control an operation of the circuit (1a) having the analog circuit. This makes it possible to use a manufactured analog circuit with good precision, and to realize an electronic circuit device that allows reduction of (i) electric power consumption of the analog circuit and (ii) circuit scale thereof.

### TECHNICAL FIELD

The present invention relates to an adjustment for electric power consumption of an analog circuit provided in a circuit. Particularly, the present invention relates to an A/D converting circuit for converting an analog input value into a digital value and outputting the digital value.

### BACKGROUND ART

An example of a circuit including analog circuits is an A/D converting circuit for converting an analog input value into a digital value and outputting the digital value. Among various types of A/D converting circuit, a pipeline A/D converting circuit is described in detail in Non-patent citation 1 (“A 10b, 20 Msample/s, 35 mW Pipeline A/D Converter”, IEEE JOURNAL OF SOLID-STATE CIRCUITS, VOL. 30, NO. 3, MARCH 1995). The pipeline A/D converting circuit carries out high-speed A/D conversion with the use of a plurality of stages. FIG. 11 illustrates a structure of such a pipeline A/D converting circuit 100. The pipeline A/D converting circuit 100 includes a plurality of stages (STAGE 1 through STAGE N) 106 through 109. A k-th (k=1 to N−1) one (STAGE k) of the stages includes a sub A/D converter 101, a sub D/A converter 102, an adder 103, and a multiply-by-n amplifier 104. The sub A/D converter 101 carries out A/D conversion with respect to an input signal Vres(k−1) and outputs a digital value Dk. The sub D/A converter 102 converts the digital value Dk, which is a result of the A/D conversion carried out by the sub A/D converter 101, into an analog value. The adder 103 adds the output of the sub D/A converter 102 to the input signal Vres(k−1), i.e., finds a difference between the analog input of the STAGE k and the digital output of the sub D/A converter 102. The multiply-by-n amplifier 104 multiplies the result of the addition by n times, and outputs the multiplied result in an analog manner. The example herein assumes that the result of the addition is multiplied by 2, and this multiple number is hereinafter referred to as “gain”. The respective functions of the adder 103 and the multiply-by-2 amplifier 104 are realized by a multiply-by-2 amplifying circuit 111. The analog output sent from the multiply-by-2 amplifying circuit 111 serves as an input signal Vres(k) to be sent to the next stage. Further, the pipeline A/D converting circuit 100 includes a bias voltage generating circuit 105 that generates a bias voltage Vb for use in an operation of the multiply-by-n amplifier 104 and that supplies the bias voltage Vb to the multiply-by-n amplifier 104 of each of the stages.

The stage 106, the first stage, receives an input signal Vres0 and outputs a digital output D1 serving as an MSB (Most Significant Bit). A difference between the input signal Vres0 and the digital output D1 is multiplied by 2, with the result that a digital output D2 of the next stage 107 has a weight the half of that of the MSB. Thereafter, an analog signal obtained by multiplying by 2 a difference between an analog input sent to each stage and a digital output generated in the stage is supplied from one stage to another until the final stage (STAGE N) 109. Note that the final stage (STAGE N) does not need to send a signal to a next stage, so that the final stage is made up of only a sub A/D converter 101. The number (N) of the stages is determined according to a required precision (bit number) N. The N-number of stages are connected to one another in the form of a pipeline as shown in FIG. 1, thus constituting the pipeline A/D converter 100. The digital outputs respectively obtained from the stages are so integrated by an error correcting circuit 110 as to be a final digital output Dout of the pipeline A/D converter 100. The pipeline A/D converting circuit 100 carries out pipeline processing, so that each of the stages may operate at a speed as fast as the conversion speed. Thus, the pipeline A/D converting circuit 100 is excellent in balance of the conversion speed, the precision, and current consumption. Such a pipeline A/D converting circuit 100 is most frequently used as an A/D converting circuit, which carries out sampling at several hundred M and allows for a precision of approximately 10 bits to 12 bits.

Explained next is a structure of the switched capacitor circuit (multiply-by-n amplifying circuit) 111 allowing realization of the respective functions of the adder 103 and the multiply-by-n amplifier 104 of each of the stages. The gain is, e.g., 2 in the structure, so that the multiply-by-n amplifier 104 is a multiply-by-2 amplifier. The multiply-by-2 amplifying circuit 111 multiplies, by 2, a difference between an input signal Vres(k−1) and an output signal VDAC of the sub D/A converter 102, and outputs, from its differential output terminal, an output signal Vres(k) thus obtained through the amplification. The multiply-by-2 amplifying circuit 111 includes an amplifier 112, switches SW1, SW2, and SW3, and capacitors Cf and Cs. Note that FIG. 11 merely illustrates one state of the circuit connected to a differential input terminal of the amplifier 112. In the other state, members of the circuit operate in a manner opposite to the manner in which the members operate in the one state. For this reason, FIG. 11 does not illustrate the other state of the circuit. The amplifier 112 is supplied with the bias voltage Vb. Each of the capacitors Cf and Cs has one electrode connected to an input terminal of the amplifier 112. The switch SW 1 switchably connects the other electrode of the capacitor Cf to either one of (i) the input terminal to which the input signal Vres(k−1) is supplied and (ii) the output terminal of the amplifier 112. The switch SW2 switchably connects the other electrode of the capacitor Cs to either one of (i) the input terminal to which the input signal Vres(k−1) is supplied and (ii) the input terminal to which the signal VDAC is supplied. The switch SW3 detachably connects the input terminal of the amplifier 112 to the input terminal to which a reference voltage Vref is supplied.

While the multiply-by-2 amplifying circuit 111 having such a structure is in a mode of sampling the input signal Vres(k−1), the switch SW1 connects the other electrode of the capacitor Cf to the input terminal to which the input signal Vres(k−1) is supplied, and the switch SW2 connects the other electrode of the capacitor Cs to the input terminal to which the input signal Vres(k−1) is supplied, and the switch SW3 connects the input terminal of the amplifier 112 to the input terminal to which the reference voltage Vref is supplied. With this, an electric charge determined by a difference between the voltage of the input signal Vres(k−1) and the reference voltage Vref is accumulated in each of the capacitors Cf and Cs.

On the other hand, during a hold mode of outputting the output signal Vres(k), the switch SW1 connects the other electrode of the capacitor Cf to the output terminal of the amplifier 112, and the switch SW2 connects the other electrode of the capacitor Cs to the input terminal to which the signal VDAC is supplied, and the switch SW3 separates the input terminal of the amplifier 112 from the input terminal to which the reference voltage Vref is supplied. This attains (i) storage of the electric charges respectively accumulated in the one electrodes of the capacitors Cf and Cs separated by the switch SW3 from the input terminal to which the reference voltage Vref is supplied; and (ii) application of a voltage, determined by the signal VDAC and the output voltage of the amplifier 112, to the input terminal of the amplifier 112.

An input/output relation in each stage including such a multiply-by-2 amplifying circuit 111 is expressed by the following Formula 1:
Vᵣₑₛ₁=2·(Vᵣₑₛ₀−V_{DAC})V_{DAC}=±0.5Vr,0 [Formula 1]
In consideration of properties of the device, Formula 1 is changed to the following Formula 2:

$$\begin{matrix}{V}_{resl} = ( 1 + \frac{{C}_{s}}{{C}_{f}} ) \cdot ( \frac{1}{1 + \frac{1}{Af}} ) \cdot \\ ( {V}_{res0} - {V}_{DAC} ) {V}_{DAC} = \pm 0.5 Vr , 0\end{matrix} \qquad [ Formula 2 ]$$

where a symbol “A” indicates a DC gain of the amplifier 112, and a symbol “f” indicates a feedback factor. When the capacitances of the capacitors Cs and Cf ideally match with each other, i.e., are equal to each other and “A” is infinite, Formula 2 coincides with Formula 1.

Each of FIG. 12(a) through FIG. 12(e) illustrates a relation (input/output relation) between (i) the input voltage Vin (input signal Vres(k−1)) supplied to the multiply-by-2 amplifying circuit 111 and (ii) the output voltage Vout (output signal Vres(k)) sent therefrom. Specifically, FIG. 12(a) illustrates a designed relation therebetween. In the designed relation, when the bit value (digital value Dk) obtained by the sub A/D converter 101 is judged to be 1, a value obtained by subtracting (i) the input voltage supplied to the sub A/D converter 101 from (ii) the threshold voltage is multiplied by 2 and is outputted from the multiply-by-2 amplifying circuit 111. On the other hand, when the bit value (digital value Dk) is judged to be 0, the input voltage supplied to the sub A/D converter 101 is multiplied by 2 and the output voltage thus multiplied is outputted therefrom. The output voltage Vout falls within a range from −Vref to +Vref. When the input voltage is equal to the threshold voltage, the input voltage is indicative of 0.

Each of FIG. 12(b) through FIG. 12(d) illustrates a case where the input/output relation is deviated from the aforementioned ideal input/output relation due to manufacturing variation of the amplifier. Specifically, FIG. 12(b) illustrates a case where the output voltage Vout falls within a range smaller than the range from −Vref to +Vref. FIG. 12(c) illustrates a case where the range of the output voltage Vout is deviated from the range from −Vref to +Vref because an electric charge irrelevant to the signal is accumulated in each of the capacitors Cf and Cs as an offset electric charge when the electric charge is injected into each of the capacitors Cf and Cs in the sampling mode and the hold mode. FIG. 12(d) illustrates a case where the output voltage Vout corresponding to the input voltage Vin is deviated due to an offset phenomenon that a value of an output of a comparator provided in the sub A/D converter 101 is reversed at a voltage away from the threshold voltage when the sub A/D converter 101 compares the input voltage Vin (input signal Vres(k−1)) with the threshold voltage. FIG. 12(e) illustrates a case where the input/output relation is deviated from the ideal input/output relation due to mismatch in the capacitances of the capacitors Cs and Cf.

Capacitance mismatching is in reverse proportion to square root of a capacitance. Therefore, when such a pipeline A/D converting circuit is applied to a 12 bit or greater high precision A/D converting circuit, the first stage thereof needs to have a fairly large capacitance and the amplifier 104 needs to have a fairly large DC gain A. This results in increase of a circuit area and increase of current consumption. For this reason, it is difficult to use this pipeline structure directly in an application having limitations in current consumption. A specific example of such an application is a mobile phone or the like. Further, the capacitance mismatching and the DC gain of the amplifier 104 are static properties. Considered in view of this is a method for correcting these properties of an analog circuit through processing carried out by a digital circuit. That is, the precision is not realized only by analog circuit designing. Such a method is described in Non-patent citation 2 (“A 15b, 1-Msample/s Digitally Self-Calibrated Pipeline ADC”, IEEE JOURNAL OF SOLID-STATE CIRCUITS, VOL. 28, NO. 12, DECEMBER 1993) and Non-patent citation 3 (“Digitally Self-Calibrating 14-bit 10-MHz CMOS Pipelined A/D Converter” IEEE JOURNAL OF SOLID-STATE CIRCUITS, VOL. 37, NO. 6, JUNE 2002).

However, an analog circuit such as the pipeline A/D converting circuit is designed with a margin in consideration of device variation, distortion, and the like, even when the properties of the analog circuit are to be corrected by a digital circuit. If the margin is too large, current consumption and an area are increased, with the result that cost is increased.

For example, MOS transistors constituting the amplifier 112 shown in FIG. 11 and provided in an IC chip have manufacturing variation in their threshold values. Also, MOS transistors constituting one amplifier 112 and provided in an IC chip have manufacturing variation in their threshold values with respect to the threshold values of MOS transistors constituting other amplifier 112 and provided in an IC chip. Therefore, the MOS transistors are fed with an operation voltage by which a MOS transistor having the highest threshold value operates normally, so that all the MOS transistors normally operate. Setting of such a sufficient operation voltage is one example of the designing with a margin. In this case, in response to application of such a sufficient operation voltage, larger currents flow in MOS transistors having lower threshold values but smaller currents flow in MOS transistors having higher threshold values. As such, the setting of the operation voltage with a margin causes increase of electric power consumption in a circuit portion having the MOS transistors in which larger currents flow.

With regard to the above example, FIG. 13 illustrates a settling property of the output voltage Vout sent from the multiply-by-2 amplifying circuit 111 including the amplifier 112. Specifically, FIG. 13 illustrates how the output voltage Vout is changed from (i) start of the hold mode in which the multiply-by-2 amplifying circuit 111 outputs an output voltage, to (ii) a predetermined time t. The output voltage Vout is determined according to manufacturing variation of the multiply-by-2 amplifying circuit 111. The output voltage Vout needs to be settled to a predetermined voltage V1 by no later than a predetermined time t1 from the start of the hold mode. Now, see curved lines c1 through c5 in FIG. 13. A time (settling time) required for settling the output voltage Vout of the multiply-by-2 amplifying circuit 111 to the predetermined voltage V1 varies according to a magnitude of a current flowing through the amplifier 112. In cases where a large current flows through the amplifier 112, the output voltage Vout rises at a large slew rate as indicated by the curved line c1, so that the settling time is short. On the other hand, in cases where a small current flows through the amplifier 112, the output voltage Vout rises at a small slew rate as indicated by the curved line c4, so that the settling time is long. Further, in cases where too a small current flows therethrough, the predetermined time t1 has elapsed before the output voltage Vout reaches the predetermined voltage V1, as indicated by the curved line c5. As a result, it is impossible to obtain a normal output voltage Vout within the sampling interval. The length of a settling period, i.e., a period from (i) a time at which the output voltage Vout is settled to the predetermined voltage V1 to (ii) the predetermined time t1 corresponds to the magnitude of the margin. As such, the settling time is short in a circuit having a large margin; however, electric power consumption is accordingly large therein. Note that: the description herein does not take into consideration (i) on-resistances of the switches, and (ii) a parasitic component in wiring.

In cases where an analog circuit having a fixed settling property is used in an application in which sampling speed is changeable, the settling time of the output voltage Vout is unchanged irrespective of the sampling speed. However, when the sampling time becomes longer, a period of time from the settlement to the extraction of the output voltage Vout becomes longer by the extended time of the sampling time, with the result that the margin is unnecessarily large in a mode in which the sampling time is long. For example, consider a case where it is allowed that sampling is carried out at such a sampling speed that the output voltage Vout reaches the voltage V1 by no later than a predetermined time t2 coming after the predetermined time t1 as shown in FIG. 13. In this case, the settling property indicated by the curved line c5 is sufficient. However, when the MOS transistors are supplied with such a current that causes the output voltage Vout to reach the voltage V1 by no later than the predetermined time t1, the settling period becomes longer by time t2−t1 as compared with that in the aforementioned case (see curved lines c1 through c5). As such, in the case where the sampling speed is changeable but the current consumption is constant in the analog circuit, the current consumption is too much and is more than necessary while the analog circuit operates at a slow speed. This is a problem.

What are considered to solve such a problem are: (i) to provide a plurality of bias voltage generating circuits each for supplying a bias voltage to an amplifier; (ii) to arrange a bias voltage generating circuit such that the bias voltage generating circuit can change an output voltage to be sent therefrom; and the like. However, normally, an analog circuit has manufacturing property variation, so that it is impossible to estimate a property that the analog circuit will have when manufactured. Therefore, even if an analog circuit is provided with a bias voltage generating circuit that can change an output voltage to be sent therefrom, it is difficult to determine a setting value for the output voltage.

### DISCLOSURE OF INVENTION

The present invention is made in light of the conventional problems, and its object is to realize an electronic circuit device that makes it possible to (i) use a manufactured analog circuit with good precision and (ii) reduce electric power consumption of the analog circuit and circuit scale thereof.

To achieve the object, an electronic circuit device of the present invention includes: an analog circuit; detecting means for detecting a predetermined property of the analog circuit; and control means for adjusting electric power consumption in the analog circuit in accordance with a result of the detection carried out by the detecting means.

According to the invention above, the predetermined property of the analog circuit having manufacturing variation is detected, and the electric power consumption of the analog circuit is adjusted in accordance with the property thus detected, with the result that the analog circuit can be controlled. This allows for (i) precision improvement whose realization is difficult only by parameter setting of the analog circuit and (ii) reduction of electric power consumption. Accordingly, a manufactured analog circuit can be used with good precision, and an electronic circuit device allowing reduction of electric power consumption and circuit scale of the analog circuit can be realized.

To achieve the object, an electronic circuit device of the present invention includes: an analog circuit; detecting means for detecting a predetermined property of the analog circuit; and control means for adjusting current consumption in the analog circuit in accordance with a result of the detection carried out by the detecting means.

According to the invention above, the predetermined property of the analog circuit having manufacturing variation is detected, and the current consumption of the analog circuit is adjusted in accordance with the property thus detected, with the result that the analog circuit can be controlled. This allows for (i) precision improvement whose realization is difficult only by parameter setting of the analog circuit and (ii) reduction of current consumption. Accordingly, a manufactured analog circuit can be used with good precision, and an electronic circuit device allowing reduction of electric power consumption and circuit scale of the analog circuit can be realized.

To achieve the object, the electronic circuit device of the present invention may be arranged such that: the predetermined property is at least one of (i) a property obtained in a part of a process of manufacturing the electronic circuit device, and (ii) a property obtained when the electronic circuit device is used.

According to the invention above, the predetermined property of the analog circuit can be detected upon manufacturing the electronic circuit device, in order to know the manufacturing variation of the analog circuit. Alternatively, the predetermined property of the analog circuit can be detected upon using the electronic circuit device, in order to know a use condition and aging of the analog circuit in addition to the manufacturing variation thereof. Alternatively, the predetermined property of the analog circuit can be detected upon manufacturing and using the electronic circuit device. This makes it possible to know a property beneficial for a user.

To achieve the object, the electronic circuit device of the present invention may be arranged such that: the detecting means detects the predetermined property of the analog circuit as a coefficient.

According to the invention above, the predetermined property of the analog circuit, and an operation condition including a condition outside the analog circuit can be processed as a signal value.

To achieve the object, the electronic circuit device of the present invention may be arranged such that: the detecting means detects a plurality of the predetermined properties as a coefficient by carrying out calculation.

According to the invention above, it is possible to efficiently detect a plurality of predetermined properties.

To achieve the object, the electronic circuit device of the present invention may be arranged such that: the coefficient is a digital signal, and the detecting means is a circuit for carrying out digital processing.

According to the invention above, in cases where a circuit including the analog circuit outputs a digital value and where a circuit including the analog circuit outputs the coefficient as a digital value, the detecting means carries out the digital processing with respect to the digital output value, with the result that the digital output of the circuit including the analog circuit can be used most efficiently and no additional analog circuit is required.

To achieve the object, the electronic circuit device of the present invention may be arranged such that: an operation condition of the analog circuit is adjusted by a digital signal, and the control means is a circuit for (i) carrying out digital processing so as to generate, in accordance with the result of the detection, the signal for adjusting the operation condition of the analog circuit, and (ii) outputting the signal.

According to the invention above, in cases where the circuit including the analog circuit outputs a digital value and where the circuit including the analog circuit outputs the coefficient as a digital value, the control means receives the coefficient as a digital value and carries out the digital processing thereto, with the result that the digital output of the circuit including the analog circuit can be used most efficiently and no additional analog circuit is required.

To achieve the object, the electronic circuit device of the present invention may be arranged such that: the detection of the coefficient and control carried out by the control means are autonomously carried out in an IC.

According to the invention above, no instruction for signal processing needs to be supplied from outside of the IC.

To achieve the object, the electronic circuit device of the present invention may be arranged such that: the analog circuit includes an amplifier, and the control means adjusts current consumption of the amplifier so as to adjust the current consumption of the analog circuit.

According to the invention above, it is possible to reduce and restrain current consumption of the amplifier.

To achieve the object, the electronic circuit device may be arranged such that: the analog circuit includes a bias voltage generating circuit for generating a bias voltage to be supplied to the amplifier, and the control means changes the bias voltage to be generated by the bias voltage generating circuit, so as to adjust the current consumption of the analog circuit.

According to the invention above, the bias voltage to be supplied from the bias voltage generating circuit to the amplifier having the manufacturing variation can be set such that a minimally required current flows in the amplifier. This reduces and restrains current consumption.

To achieve the object, the electronic circuit device of the present invention may be arranged such that: the bias voltage generating circuit changes, according to an input current, the bias voltage to be generated.

According to the invention above, in the case of using such a bias voltage generating circuit that changes the bias voltage according to the input current, current consumption in the amplifier can be reduced and restrained.

To achieve the object, the electronic circuit device of the present invention may be arranged such that: the bias voltage generating circuit simultaneously changes, according to the input current, a plurality of the bias voltages to be generated.

According to the invention above, in the case of using such a bias voltage generating circuit for an amplifier using a plurality of bias voltages, current consumption in the amplifier can be reduced and restrained.

To achieve the object, the electronic circuit device of the present invention may be arranged such that: the bias voltage generating circuit is a D/A converting circuit which changes, according to an input digital signal, the bias voltages to be generated.

According to the invention above, the bias voltages to be generated can be changed by changing the input digital signal. This makes it possible to efficiently control the bias voltages with the use of a digital signal obtained by processing the coefficient, the digital value, sent from the A/D converting circuit.

To achieve the object, the electronic circuit device of the present invention may be arranged such that: the bias voltage generating circuit generates said plurality of the bias voltages, and includes a plurality of the D/A converting circuits provided so as to respectively correspond to said bias voltages.

According to the invention above, the bias voltage generating circuit uses the D/A converting circuits to change the bias voltages, individually.

To achieve the object, the electronic circuit device of the present invention may be arranged such that: the number of the D/A converting circuits coincides with the number of said bias voltages to be supplied to the amplifier.

According to the invention above, the number of the bias voltages to be generated coincides with the number of the bias voltages to be used by the amplifier. This makes it possible to efficiently generate bias voltages.

To achieve the object, the electronic circuit device of the present invention may be arranged such that: the bias voltage generating circuit is brought into an operation state by a bias voltage setting signal supplied from outside.

According to the invention above, the bias voltage generating circuit is brought into the operation condition only when bias voltage setting needs to be carried out again. This allows reduction of electric power consumption.

To achieve the object, the electronic circuit device may be arranged such that: in order to adjust the current consumption of the analog circuit, the control means repeatedly changes the bias voltage to be generated by the bias voltage generating circuit, until the coefficient reaches a convergence value set in advance.

According to the invention above, the bias voltage to be supplied to the amplifier can be determined by changing the bias voltage until the bias voltage is converged in a required correction value. This allows the amplifier to be always fed with an optimum bias voltage.

To achieve the object, the electronic circuit device of the present invention further includes: correcting means for correcting, in accordance with the coefficient, an output result obtained according to an operation condition of the analog circuit.

According to the invention above, an output error of the circuit including the analog circuit can be corrected.

To achieve the object, the electronic circuit device of the present invention may be arranged such that: the analog circuit is provided in an A/D converting circuit for converting an analog input signal into a digital value, and outputting the digital value.

According to the invention above, there are found (i) the coefficient indicating the predetermined property of the analog circuit having the manufacturing variation and (ii) the operation condition including the condition outside the analog circuit, and the A/D converting circuit can be controlled by adjusting the operation condition of the analog circuit in accordance with the property. This allows for (i) precision improvement whose realization is difficult only by parameter setting of the analog circuit, and (ii) reduction of the current consumption. Accordingly, the analog circuit provided in the manufactured A/D converting circuit can be used with good precision, and such an electronic circuit device that reduces electric power consumption and circuit scale of the analog circuit can be realized.

To achieve the object, the electronic circuit device of the present invention further includes: correcting means for correcting, in accordance with the coefficient, the digital value obtained by the A/D conversion carried out by the A/D converting circuit.

According to the invention above, it is possible to correct an error of the A/D conversion carried out by the A/D converting circuit.

To achieve the object, the electronic circuit device of the present invention may be arranged such that: the A/D converting circuit is a pipeline A/D converting circuit.

According to the invention above, the operation condition of the analog circuit provided in the pipeline A/D converting circuit, which is an A/D converting circuit excellent in balance among conversion speed, precision, and current consumption, is adjusted in accordance with (i) the detected predetermined property of the analog circuit and (ii) the detected operation condition including the condition outside the analog circuit. With this, the output of the analog circuit is good in quality to some extent even before correction. Therefore, in cases where correcting means for correcting the digital output of the result of the A/D conversion carried out by the A/D converting circuit is provided, it is possible to reduce load to be imposed on the correction means.

To achieve the object, the electronic circuit device of the present invention may be arranged such that: the coefficient is an index of a gain of an amplifier provided in each of stages of the A/D converting circuit, which stages are provided in a form of a pipeline.

According to the invention above, no new circuit for generating the coefficient is required because the gain, the coefficient, is to be found anyway for A/D conversion in a structure for correcting and outputting a result of the A/D conversion.

To achieve the object, the electronic circuit device of the present invention may be arranged such that: the coefficient is an index of a gain error of an amplifier provided in each of stages of the A/D converting circuit, which stages are provided in a form of a pipeline.

According to the invention above, no new circuit for generating the coefficient is required because the gain error, the coefficient, is to be found anyway for A/D conversion in the case of a structure for correcting and outputting a result of the A/D conversion.

To achieve the object, the electronic circuit device of the present invention further includes: bias voltage generating circuits, which generate bias voltages to be supplied to amplifiers of the pipeline A/D converting circuit, and which are provided so as to correspond to-a plurality of stages of the pipeline A/D converting circuit respectively.

According to the invention above, the bias voltage setting can be carried out with respect to the stages, individually.

To achieve the object, the electronic circuit device may be arranged such that: the bias voltages are sequentially determined in an order from a latter stage to an earlier stage of the pipeline A/D converting circuit.

According to the invention above, optimum bias voltage setting can be carried out with respect to each of the stages, so that each of the stages in the pipeline A/D converting circuit can operate with an optimum current value.

To achieve the object, the electronic circuit device of the present invention may be arranged such that: the bias voltages are sequentially determined in an order from a final stage to a first stage of stages respectively including the amplifiers.

According to the invention above, optimum bias voltage setting can be carried out with respect to each of the stages, so that each of the stages in the pipeline A/D converting circuit can operate with an optimum current value.

To achieve the object, the electronic circuit device of the present invention may be arranged such that: each of the bias voltage generating circuits respectively corresponding to the stages of the pipeline A/D converting circuit is brought into an operation state by a bias voltage setting signal supplied from outside.

According to the invention above, upon requested by way of the bias voltage setting signal, the bias voltage setting can be carried out only with respect to a stage that needs bias voltage setting.

As such, to achieve the object, the electronic circuit device of the present invention includes: an analog circuit; detecting means for detecting a predetermined property of the analog circuit and/or an operation condition including a condition outside the analog circuit; and control means for adjusting either electric power consumption or current consumption in the analog circuit in accordance with a result of the detection carried out by the detecting means. This makes it possible to use a manufactured analog circuit with good precision, and to realize an electronic circuit device that allows electric power consumption and circuit scale of the analog circuit.

### BRIEF DESCRIPTION OF DRAWINGS

FIG. 1 is a block diagram illustrating a main structure of a first electronic circuit device of Embodiment 1 of the present invention.

FIG. 2 is a block diagram illustrating a main structure of a second electronic circuit device of Embodiment 1 of the present invention.

FIG. 3 is a block diagram illustrating a main structure of a third electronic circuit device of Embodiment 1 of the present invention.

FIG. 4 is a block diagram illustrating a main structure of a fourth electronic circuit device of Embodiment 1 of the present invention.

FIG. 5 is a circuit block diagram illustrating a structure of an amplifier provided in the electronic circuit device shown in FIG. 4.

FIG. 6 is a circuit diagram illustrating a first example of a structure of a bias voltage generating circuit provided in the electronic circuit device shown in FIG. 4.

FIG. 7 is a circuit block diagram illustrating a second example of the structure of the bias voltage generating circuit provided in the electronic circuit device shown in FIG. 4.

FIG. 8 is a flowchart illustrating a flow how the electronic circuit device shown in FIG. 4 carries out bias voltage setting.

FIG. 9 is a block diagram illustrating a main structure of an electronic circuit device of Embodiment 2 of the present invention.

FIG. 10 is a flowchart illustrating a flow how the electronic circuit device shown in FIG. 9 carries out bias voltage setting.

FIG. 11 is a block diagram illustrating a main structure of a conventional electronic circuit device.

FIG. 12(a) is a graph illustrating an input/output relation of an amplifier.

FIG. 12(b) is a graph illustrating an input/output relation of the amplifier.

FIG. 12(c) is a graph illustrating an input/output relation of the amplifier.

FIG. 12(d) is a graph illustrating an input/output relation of the amplifier.

FIG. 12(e) is a graph illustrating an input/output relation of the amplifier.

FIG. 13 is a graph illustrating a settling property of the amplifier.

### BEST MODE FOR CARRYING OUT THE INVENTION

### Embodiment 1

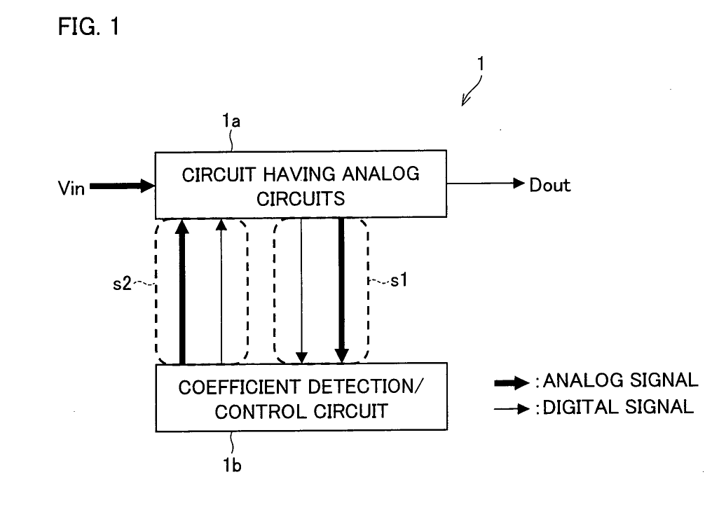

FIG. 1 is a diagram schematically illustrating an analog circuit inclusion circuit 1 (electronic circuit device) of the present invention. The analog circuit inclusion circuit 1 include a circuit 1a having analog circuits, and a coefficient detection/control circuit 1b. The circuit 1a having the analog circuits processes an analog input signal Vin. Then, the circuit 1a outputs, e.g., a digital output Dout obtained as a result of the processing, as shown in FIG. 1. Further, the circuit 1a having the analog circuits sends, to the coefficient detection/control circuit 1b, a coefficient s1 indicating a predetermined property of each of the analog circuits.

Examples of the predetermined property include (i) a voltage or current in a predetermined portion of each of the analog circuits, (ii) a value expressed by using the voltage or current, and the like. By detecting the predetermined property upon manufacturing of the analog circuit, it is possible to know manufacturing variation of the analog circuit in accordance with the property thus detected.

Further, the predetermined property encompasses a property including an effect from a condition outside the analog circuit. By detecting such a predetermined property when a user uses the analog circuit, it is possible to know a use condition and aging of the analog circuit in addition to the manufacturing variation of the analog circuit in accordance with the property thus detected. Examples of the effect from the condition outside the analog circuit includes (i) an effect caused due to a level of an input signal supplied to the analog circuit, (ii) an effect caused due to a temperature of the analog circuit, and the like. In cases where the input signal has a range smaller than a dynamic range prepared by the analog circuit, a range of an output of the analog circuit becomes narrower than the dynamic range, so that the range of the input signal influences an operation condition of the analog circuit. Further, consider a case where the temperature of the analog circuit is changed. For example, when the temperature of the analog circuit is increased, the thresholds of MOS transistors constituting the analog circuit are changed, with the result that an optimum operation condition (voltage/current condition) of the analog circuit is changed. Thus, the temperature of the analog circuit influences the operation condition of the analog circuit.

As such, the property beneficial for the user can be found as long as the detected predetermined property is at least either one of (i) the property that the analog circuit has upon manufacturing of the analog circuit, and (ii) the property that the analog circuit has when the analog circuit is used. This is also true in embodiments described below.

The coefficient s1 indicates a signal value and may be an analog signal or a digital signal. Note that each digital signal in the structure shown in FIG. 1 is not limited to a 1-bit digital signal but is a general digital signal to be transmitted via a predetermined bit bus. The coefficient s1 is processed and detected as a signal value by a coefficient detecting circuit (detecting means) of the coefficient detection/control circuit 1b, with the result that the property of the analog circuit is detected. In cases where the coefficient s1 is a digital signal, the coefficient detection/control circuit 1b may detect the predetermined property in accordance with either the digital value of the coefficient s1 or a value obtained by processing the digital value. Then, a control circuit (control means) of the coefficient detection/control circuit 1b sends, to the circuit 1a having the analog circuit, a control signal s2 that is according to the obtained detection result of the coefficient s1. The control signal s2 may be an analog signal or a digital signal. In this way, the coefficient detection/control circuit 1b adjusts the operation condition of the analog circuit so as to control the operation of the circuit 1a having the analog circuit.

The adjustment of the operation condition of the analog circuit makes it possible to control the circuit 1a having the analog circuit, so as to reduce electric power consumption in the analog circuit as much as possible while keeping the predetermined property to be a desired property so as not to affect the result of the processing carried out by the circuit 1a. For example, the predetermined property is kept to be a desired property such that: every time the circuit 1a having the analog circuit receives an input voltage Vin, the circuit 1a outputs an output Dout corresponding to the input voltage Vin. Therefore, even though the analog circuits have manufacturing variation in their properties, it is possible to carry out electric power consumption reduction in accordance with the property of each of the manufactured analog circuits. Further, while manufacturing an analog circuit that is so designed in view of avoidance of too large a margin as to be provided together with a circuit that is capable of changing and setting a parameter of the analog circuit in order to handle (i) property variation caused upon the manufacturing and (ii) various use modes, it is impossible to estimate a property that the analog circuit will have upon completion of the manufacturing. Therefore, it is difficult to carry out an appropriate parameter setting after the manufacturing. However, according to the structure shown in FIG. 1, the property of the manufactured analog circuit is detected, so that the manufactured analog circuit can be used with good precision.

Note that: when the coefficient detecting circuit (detecting means) detects the property including the effect from the condition outside the analog circuit, the control circuit (control means) carries out the following control, for example. When an input signal received by the analog circuit has a range smaller than the dynamic range prepared by the analog circuit, an output signal to be sent from the analog circuit will have a small range. Therefore, the control circuit detects the range of the signal sent to the analog circuit, so as to carry out control of reducing a current in the analog circuit by a current for an operation handling the unnecessary part of the dynamic range prepared by the analog circuit. Further, when the temperature of the analog circuit is increased, the threshold of each MOS transistor is changed, with the result that a current flowing in the MOS transistor is changed. The current is detected, and the control circuit adjusts, in accordance with the detected current, a voltage to be applied to the MOS transistor. That is, the control circuit carries out control of adjusting the current. This is also true in the embodiments described below.

Note that: in all the embodiments including the present embodiment, it is assumed that a power supply voltage of the analog circuit is constant in a fluctuation range under conditions that current consumption can be reduced. With this, electric power consumption is reduced. A way of reducing electric power consumption is not limited to this, and electric power consumption may be reduced by reducing a voltage while keeping a current constant, or by reducing a current and a voltage.

As such, according to the structure shown in FIG. 1, the circuit having the analog circuits each having manufacturing variation in the predetermined property can be controlled by (i) finding the coefficient that indicates the predetermined property of each of the analog circuits and that indicates the operation condition including the condition outside the analog circuit, and (ii) adjusting the operation condition of the analog circuit in accordance with the property. This allows for (i) precision improvement whose realization is difficult only by carrying out parameter setting of the analog circuit, and (ii) reduction of current consumption. With this, it is possible to use the manufactured analog circuit with good precision, and to realize such an electronic circuit device that allows reduction of power consumption and circuit scale of the analog circuit.

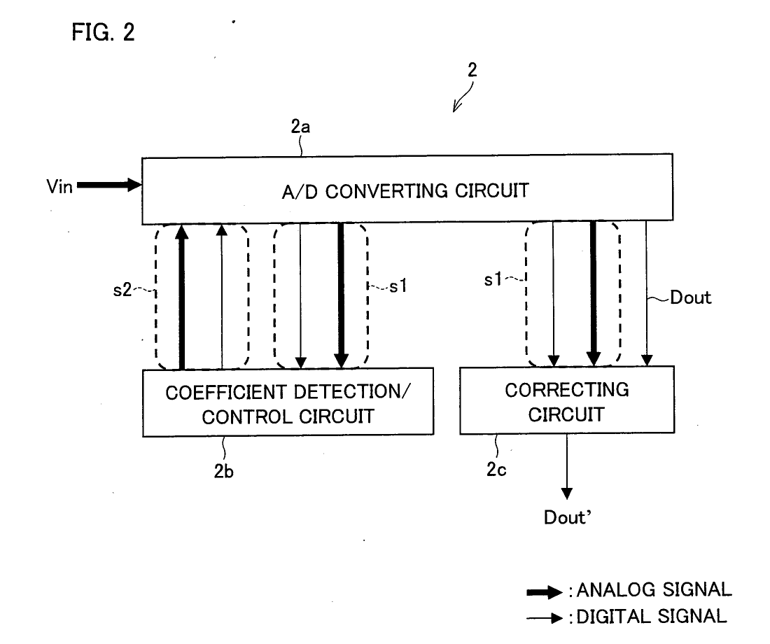

FIG. 2 illustrates a structure of an A/D converting circuit inclusion circuit (electronic circuit device) 2. The A/D converting circuit inclusion circuit 2 constitutes a correction type A/D converting circuit, and includes an A/D converting circuit 2a, a coefficient detection/control circuit 2b, and a correcting circuit 2c. The A/D converting circuit (circuit having analog circuits) 2a carries out A/D conversion with respect to an analog input signal Vin supplied thereto, and sends a digital output Dout to the correcting circuit 2c. Further, the A/D converting circuit 2a sends, to the coefficient detection/control circuit 2b and the correcting circuit 2c, a coefficient s1 indicating a predetermined property of each of analog circuits provided in the A/D converting circuit 2a.

The coefficient s1 indicates a signal value, and may be an analog signal or a digital signal. Note that each digital signal in the structure shown in FIG. 2 is not limited to a 1-bit digital signal but is a general digital signal to be transmitted via a predetermined bit bus.

The coefficient s1 is processed and detected as a signal value by a coefficient detecting circuit (detecting means) of the coefficient detection/control circuit 2b, with the result that the property of the analog circuit is detected. In cases where the coefficient s1 is a digital signal, the coefficient detection/control circuit 2b may detect the predetermined property in accordance with either the digital value of the coefficient s1 or a value obtained by processing the digital value. Then, a control circuit (control means) of the coefficient detection/control circuit 2b generates and sends; to the A/D converting circuit 2a, a control signal s2 that is according to the obtained detection result of the coefficient s1. The control signal s2 may be an analog signal or a digital signal. In this way, the coefficient detection/control circuit 2b adjusts the operation condition of the analog circuit so as to control the operation of the A/D converting circuit 2a.

In accordance with a result of the control, the digital output Dout of the A/D converting circuit 2a is obtained. The digital output Dout thus obtained is corrected by the correcting circuit (correcting means) 2c, and the correcting circuit 2c outputs a digital output Dout′, which is the corrected digital output Dout. In cases where an input/output relation in the A/D conversion is deviated from a desired relation due to property variation of the analog circuit provided in the A/D converting circuit 2a, an A/D conversion error is caused. However, the A/D conversion error is corrected by the correcting circuit 2c.

The adjustment of the operation condition of the analog circuit makes it possible to control the A/D converting circuit 2a, so as to reduce electric power consumption in the analog circuit as much as possible while keeping the predetermined property so as not to, e.g., affect a value of a digital output Dout corresponding to an input voltage Vin supplied to the A/D converting circuit 2a. Therefore, even though the analog circuits have manufacturing variation in their properties, it is possible to carry out electric power consumption reduction in accordance with the property of each of the manufactured analog circuits. Further, while manufacturing an analog circuit that is so designed in view of avoidance of too large a margin as to be provided together with a circuit that is capable of changing and setting a parameter of the analog circuit in order to handle (i) property variation caused upon the manufacturing and (ii) various use modes, it is impossible to estimate a property that the analog circuit will have upon completion of the manufacturing. Therefore, it is difficult to carry out an appropriate parameter setting after the manufacturing. However, according to the structure shown in FIG. 2, the property of the manufactured analog circuit is detected, so that the manufactured analog circuit can be used with good precision.

As such, according to the structure shown in FIG. 2, the A/D converting circuit having the analog circuits each having manufacturing variation in the predetermined property can be controlled by (i) finding the coefficient that indicates the predetermined property of each of the analog circuits and that indicates the operation condition including the condition outside the analog circuit, and (ii) adjusting the operation condition of the analog circuit in accordance with the property and the operation condition including the condition outside the analog circuit. This allows for (i) precision improvement whose realization is difficult only by carrying out parameter setting of the analog circuit, and (ii) reduction of current consumption. With this, it is possible to use the manufactured analog circuit with good precision, and to realize such an A/D converting circuit inclusion circuit (electronic circuit device) that allows reduction of power consumption and circuit scale of the analog circuit.

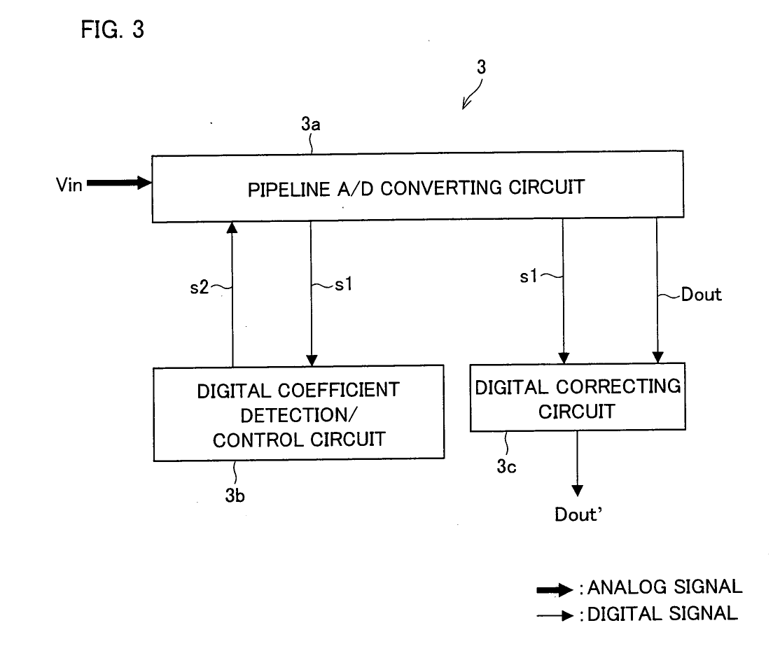

FIG. 3 illustrates a structure of an A/D converting circuit inclusion circuit 3. The A/D converting circuit inclusion circuit (electronic circuit device) 3 constitutes a correction type A/D converting circuit, and includes a pipeline A/D converting circuit 3a, a digital coefficient detection/control circuit 3b, and a digital correcting circuit 3c. The pipeline A/D converting circuit (circuit having analog circuits; A/D converting circuit) 3a carries out A/D conversion with respect to an analog input signal Vin supplied thereto, and sends a digital output Dout to the digital correcting circuit 3c. Further, the pipeline A/D converting circuit 3a sends, to the digital coefficient detection/control circuit 3b and the digital correcting circuit 3c, a coefficient s1 indicating a predetermined property of each of analog circuits provided in the pipeline A/D converting circuit 3a.

The coefficient s1 indicates a signal value, and is a digital signal. Note that each digital signal in the structure shown in FIG. 3 is not limited to a 1-bit digital signal but is a general digital signal to be transmitted via a predetermined bit bus. All the stages of the pipeline A/D converting circuit 3a except the final stage are provided with amplifiers, respectively. A property of each of the amplifiers can be used as a predetermined property of the analog circuit.

The coefficient s1 is processed and detected as a signal value by a digital coefficient detecting circuit (detecting means) of the digital coefficient detection/control circuit 3b, with the result that the property of the analog circuit is detected. The coefficient digital coefficient detecting circuit may detect the predetermined property in accordance with either the digital value of the coefficient s1 or a value obtained by processing the digital value. Then, a digital control circuit (control means) of the digital coefficient detection/control circuit 3b generates and sends, to the pipeline A/D converting circuit 3a, a control signal s2 that is according to the obtained detection result of the coefficient s1. The generation of the control signal s2 is carried out through digital processing. The control signal s2 is a digital signal. In this way, the digital control circuit adjusts the operation condition of the analog circuit so as to control the operation of the pipeline A/D converting circuit 3a.

In accordance with a result of the control, the digital output Dout of the pipeline A/D converting circuit 3a is obtained. The digital output Dout thus obtained is corrected by the digital correcting circuit (correcting means) 3c, and the digital correcting circuit 3c outputs a digital output Dout′, which is the corrected digital output Dout. In cases where an input/output relation in the A/D conversion is deviated from a desired relation due to property variation of the analog circuit provided in the pipeline A/D converting circuit 3a, an A/D conversion error is caused. However, the A/D conversion error is corrected by the digital correcting circuit 3c.

The adjustment of the operation condition of the analog circuit makes it possible to control the pipeline A/D converting circuit 3a, so as to reduce electric power consumption in the analog circuit as much as possible while keeping the predetermined property to be a desired property so as not to, e.g., affect a value of a digital output Dout corresponding to an input voltage Vin supplied to the pipeline A/D converting circuit 3a. Therefore, even though the analog circuits have manufacturing variation in their properties, it is possible to carry out electric power consumption reduction in accordance with the property of each of the manufactured analog circuits. Further, while manufacturing an analog circuit that is so designed in view of avoidance of too large a margin as to be provided together with a circuit that is capable of changing and setting a parameter of the analog circuit in order to handle (i) property variation caused upon the manufacturing and (ii) various use modes, it is impossible to estimate a property that the analog circuit will have upon completion of the manufacturing. Therefore, it is difficult to carry out an appropriate parameter setting after the manufacturing. However, according to the structure shown in FIG. 3, the property of the manufactured analog circuit is detected, so that the manufactured analog circuit can be used with good precision.

As such, according to the structure shown in FIG. 3, the pipeline A/D converting circuit having the analog circuits each having manufacturing variation in the predetermined property can be controlled by (i) finding the coefficient that indicates the predetermined property of each of the analog circuits and that indicates the operation condition including the condition outside the analog circuit, and (ii) adjusting the operation condition of the analog circuit in accordance with the property and the operation condition including the condition outside the analog circuit. This allows for (i) precision improvement whose realization is difficult only by carrying out parameter setting of the analog circuit, and (ii) reduction of current consumption. With this, it is possible to use the manufactured analog circuit with good precision, and to realize such an A/D converting circuit inclusion circuit (electronic circuit device) that allows reduction of power consumption and circuit scale of the analog circuit.

Further, the A/D converting circuit in the structure shown in FIG. 3 is a pipeline A/D converting circuit including a plurality of stages, and is excellent in balance of conversion speed, conversion precision, and current consumption. Therefore, in cases where the operation condition of each of the analog circuits of such a pipeline A/D converting circuit is adjusted in accordance with (i) the detected predetermined property of the analog circuit and (ii) the detected condition outside the analog circuit, the output of the analog circuit is good in quality to some extent even before the correction. This reduces load to be imposed on the digital correction circuit 3c.

In the meanwhile, the digital coefficient detection/control circuit 3b in the structure shown in FIG. 3 is a circuit that carries out digital processing with respect to the coefficient s1. Moreover, the digital coefficient detection/control circuit 3b generates the control signal s2 in accordance with the detection result of the coefficient s1 through digital processing, and outputs the control signal s2 thus generated. In the meanwhile, the digital correcting circuit 3c corrects the digital output Dout supplied from the pipeline A/D converting circuit 3a, in accordance with the coefficient s1. Then, the digital correcting circuit 3c outputs the digital output Dout′ obtained as a result of the correction. Since an A/D converting circuit such as the pipeline A/D converting circuit 3a generally outputs a digital value, it is possible to most efficiently process the digital output value of the A/D converting circuit in cases where a circuit for processing the output of the A/D converting circuit is a digital circuit. In this case, no additional analog circuit needs to be provided.

Note that all the stages but the final stage in the pipeline A/D converting circuit 3a are provided with the amplifiers serving as the analog circuits, respectively; however, the property detection and the operation condition adjustment may be carried out with respect to either all of the stages or some of the stages.

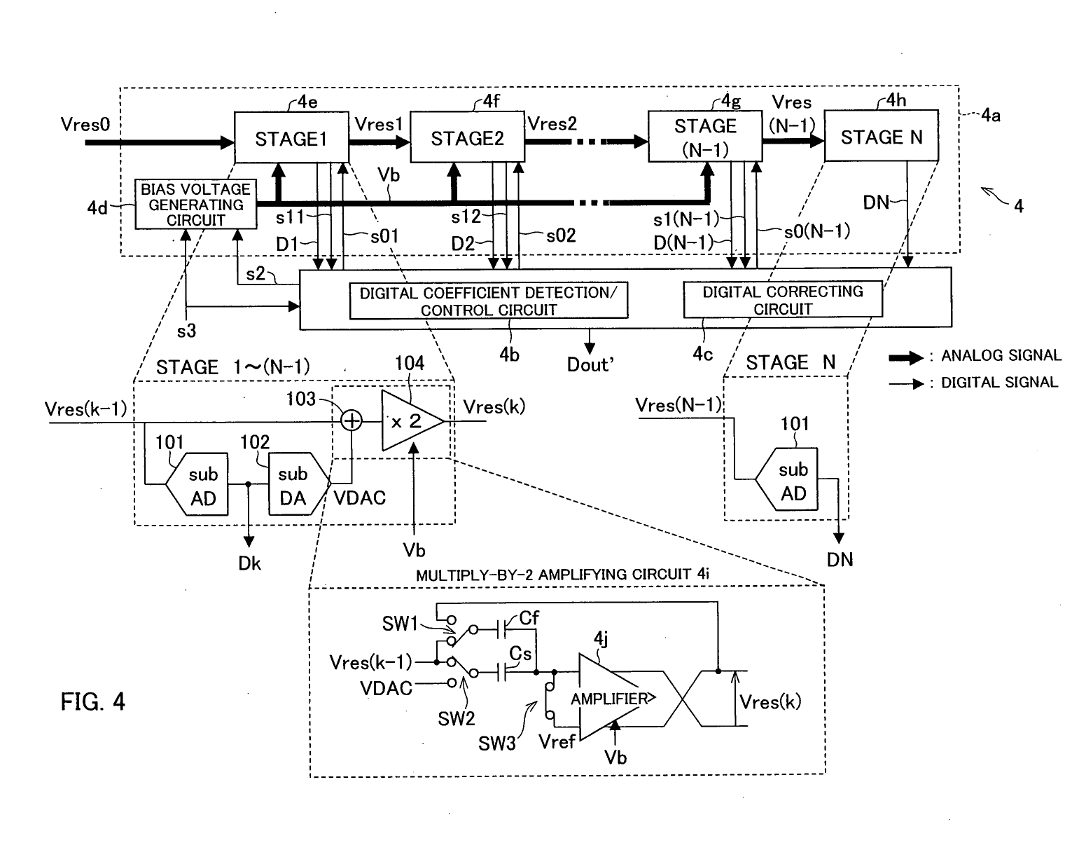

FIG. 4 illustrates a structure of an analog circuit inclusion circuit (electronic circuit device) according to the present embodiment. The analog circuit inclusion circuit has an A/D converting circuit in which analog circuits are provided. Such an A/D converting circuit inclusion circuit 4 constitutes a correction type A/D converting circuit, and includes a pipeline A/D converting circuit 4a, a digital coefficient detection/control circuit 4b, and a digital correcting circuit 4c.

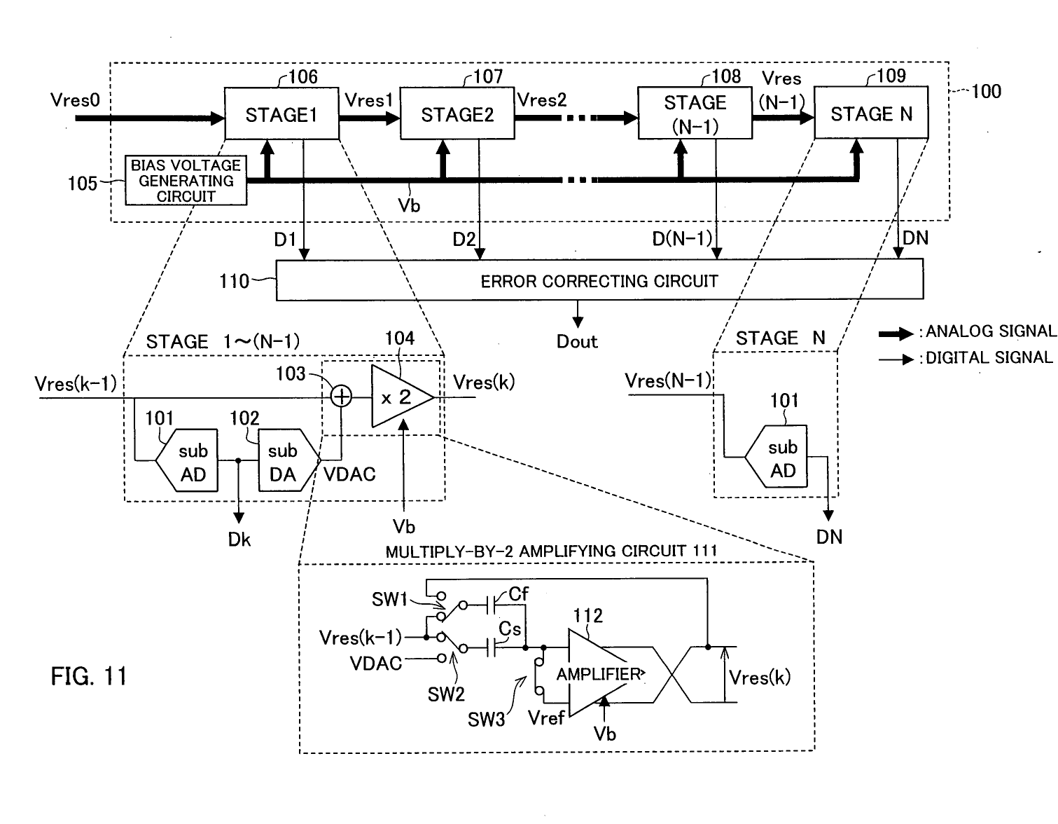

The pipeline A/D converting circuit (circuit having analog circuits; A/D converting circuit) 4a includes (i) the N-number of stages (STAGE 1 through STAGE N) 4e through 4h, and (ii) a bias voltage generating circuit 4d. A k-th (k=1 to N−1) stage (STAGE K) receives an analog input signal Vres(k−1), carries out A/D conversion with respect to the analog input signal Vres(k−1) so as to obtain a digital output DK, and sends the digital output Dk to the digital correcting circuit 4c. Further, the k-th stage has an amplifier, which is an analog circuit. The amplifier amplifies a difference between a value of the input signal Vres(k−1) and a value of a signal obtained by carrying out D/A conversion with respect to the digital output Dk, so as to obtain a signal Vresk, which is to be sent to the next stage. Then, the signal Vresk is sent thereto. The first stage (STAGE 1) 4e receives an input signal Vres0, which coincides with an input signal sent to the pipeline A/D converting circuit 4a. The final stage (STAGE N) 4h receives an input signal Vres(N−1), and carries out A/D conversion with respect to the input signal Vres(N−1) so as to obtain a digital output DN, and sends the digital output to the digital correcting circuit 4c. Each of the stages (STAGE 1 through STAGE N) 4e through 4h has a structure basically identical to the aforementioned structure described with reference to FIG. 11. The bias voltage generating circuit 4d generates bias voltages Vb to be supplied to an amplifier 4j, which is provided in the multiply-by-2 amplifying circuit 4i for amplifying the difference between the value of the input signal Vres(k−1) and the value of the signal obtained by carrying out D/A conversion with respect to the digital output Dk.

Further, the k-th (k=1 to N−1) stage (STAGE k) of the pipeline A/D converting circuit 4a sends a coefficient s1k to each of the digital coefficient detection/control circuit 4b and the digital correcting circuit 4c in response to an instruction made by way of a below-described control signal s0k sent from the digital coefficient detection/control circuit 4b. The coefficient s1k indicates a predetermined property of the multiply-by-2 amplifying circuit 4i that is the analog circuit provided in the k-th stage. At least one of the stages 1 through N−1 may output the coefficient s1k upon reception of the control signal s0k (k=1 to N−1). However, in cases where each of the stages 1 through N−1 outputs the coefficient s1k, it is possible to find a stage whose predetermined property is the most greatly deviated from a desired property, and to cope with such a stage. This will be explained later. Examples of the predetermined property include a gain of the multiply-by-2 amplifying circuit 4i and a gain error thereof, as described below. General examples of the predetermined property include a voltage or current in a predetermined portion of the multiply-by-2 amplifying circuit 4i, and a value expressed by using the voltage or current.

The coefficient s1 indicates a signal value, and is a digital signal. Note that each digital signal in the structure shown in FIG. 4 is not limited to a 1-bit digital signal but is a general digital signal to be transmitted via a predetermined bit bus. The bias voltage generating circuit 4d receives a control signal s2 described below, and changes, in accordance with the control signal s2, the bias voltages Vb to be generated.

The coefficient s1k is processed and detected as a signal value by a digital coefficient detecting circuit (detecting means) of the digital coefficient detection/control circuit 4b, with the result that the property of the multiply-by-2 amplifying circuit 4i is detected. The digital coefficient detecting circuit may detect the predetermined property in accordance with either the digital value of the coefficient s1k or a value obtained by processing the digital value. Then, a digital control circuit (control means) of the digital coefficient detection/control circuit 4b generates and sends, to the bias voltage generating circuit 4d of the pipeline A/D converting circuit 4a, the control signal s2 that is according to the obtained detection result of the coefficient s1k. The generation of the control signal s2 is carried out through digital processing. The control signal s2 is a digital signal. In this way, the digital control circuit adjusts the operation condition of the multiply-by-2 amplifying circuit 4i so as to control the operation of the pipeline A/D converting circuit 4a.

In accordance with a result of such control, a digital output Dout made up of digital outputs D1 through DN is obtained. The digital output Dout thus obtained is corrected by the digital correcting circuit (correcting means) 4c, and the digital correcting circuit 4c outputs a digital output Dout′, which is the corrected digital output Dout. In cases where an input/output relation in the A/D conversion is deviated from a desired relation due to property variation of the analog circuit provided in the pipeline A/D converting circuit 4a, an A/D conversion error is caused. However, the A/D conversion error is corrected by the digital correcting circuit 4c.

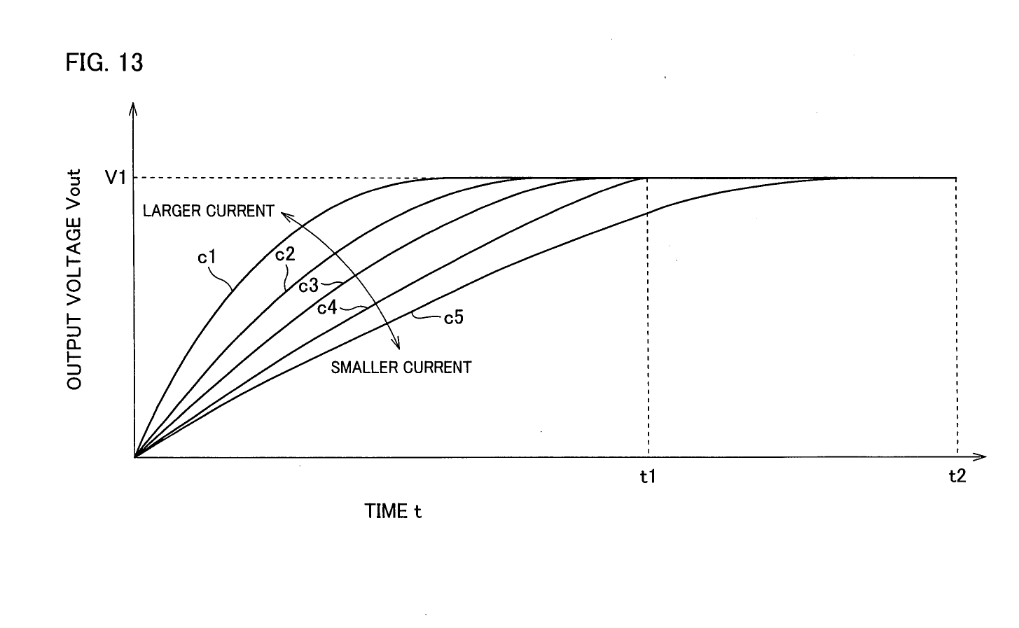

As is the case with the aforementioned explanation made with reference to FIG. 11 and FIG. 13, by changing the bias voltages Vb to be supplied from the bias voltage generating circuit 4d to the amplifier 4j of each of the stages, a value of a current flowing in the amplifier 4j is changed. Further, described in the aforementioned explanation made with reference to FIG. 13 is that: the change of a current flowing through the MOS transistors constituting the amplifier 112 causes the change of the settling time of the output voltage Vout of the multiply-by-2 amplifying circuit 111. In cases where it is allowed that the output voltage Vout is settled to the predetermined voltage V1 by no later than the predetermined time t1, the smallest current required for the settlement is such a current that allows the output voltage Vout to reach the predetermined voltage V1 at the predetermined time t1 as indicated by the curved line c4 of FIG. 13. Therefore, the structure shown in FIG. 4 finds out how a settling property of the output voltage Vout of the multiply-by-2 amplifying circuit 4i is changed (e.g., the curved lines c1 through c5 of FIG. 13) by changing the bias voltages Vb to be supplied to the amplifier 4j, in order to find a condition under which the output voltage Vout of the multiply-by-2 amplifying circuit 4i is settled in such a manner as indicated by the curved line c4.

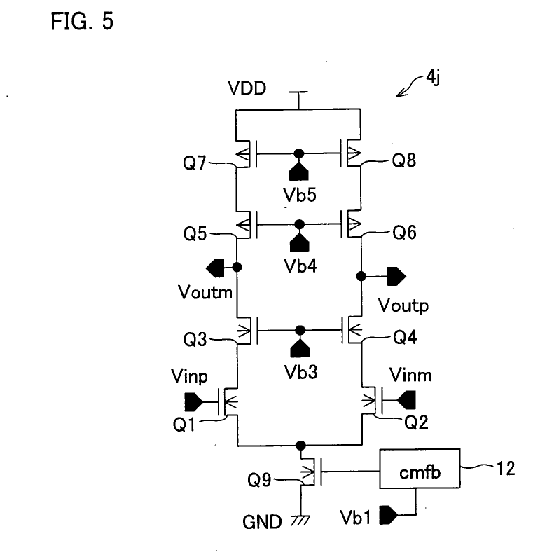

Explained next are examples of structures of (i) the amplifier 4j provided in the multiply-by-2 amplifier 4i of each of the stages, and (ii) the bias voltage generating circuit 4d. Note that these structures are mere examples. See FIG. 5. The amplifier 4j is a telescopic type amplifier provided as an amplifier in each of the stages. The amplifier 4j includes transistors Q1 through Q9, and a common mode feedback circuit 12. The transistors Q1 through Q4 and Q8 are N-channel type MOS transistors, and the transistors Q5 through Q8 are P-channel type MOS transistors, respectively.

The transistors Q1 has a source connected to a source of the transistor Q2, and the sources of the transistors Q1 and Q2 are connected to a drain of the transistor Q9. The transistor Q1 has a drain connected to a source of the transistor Q3. The transistor Q2 has a drain connected to a source of the transistor Q4. The transistor Q3 has a gate connected to a gate of the transistor Q4. The transistor Q3 has a drain connected to a drain of the transistor Q5. The transistor Q4 has a drain connected to a drain of the transistor Q6. The transistor Q5 has a gate connected to a gate of the transistor Q6. The transistor Q6 has a source connected to a drain of the transistor Q7. The transistor Q6 has a source connected to a drain of the transistor Q8. Each of the transistors Q7 and Q8 has a source connected to a power source VDD. The transistor Q7 has a gate connected to a gate of the transistor Q8.

The amplifier 4j has a differential input structure. Therefore, the amplifier 4j receives one input voltage Vinm via the gate of the transistor Q2, and receives the other input voltage Vinp via the gate of the transistor Q1. Moreover, the amplifier 4j has a differential output structure. Therefore, the amplifier 4j sends one output voltage Voutm via a node of the drain of the transistor Q3 and the drain of the transistor Q5, and sends the other output voltage Voutp via a node of the drain of the transistor Q4 and a drain of the transistor Q6.

Further, the transistor Q9 has a gate connected to the common mode feedback circuit 12, which receives a bias voltage Vb1. In accordance with the bias voltage Vb1, the common mode feedback circuit 12 determines a common voltage of a differential signal. Further, the respective gates of the transistors Q3 and Q4 receive a bias voltage Vb3. The respective gates of the transistors Q5 and Q6 receive a bias voltage Vb4. The respective gates of the transistors Q7 and Q8 receive a bias voltage Vb5. The bias voltages Vb1, Vb3, Vb4, and Vb5 are supplied from the bias voltage generating circuit 4d. The input voltages Vinm and Vinp are generated by using a bias voltage Vb2 outputted by the bias voltage generating circuit 4d, and are voltages whose values are in the vicinity of that of the bias voltage Vb2, as is the case with the input voltage received by the amplifier 112 and explained with reference to FIG. 11.

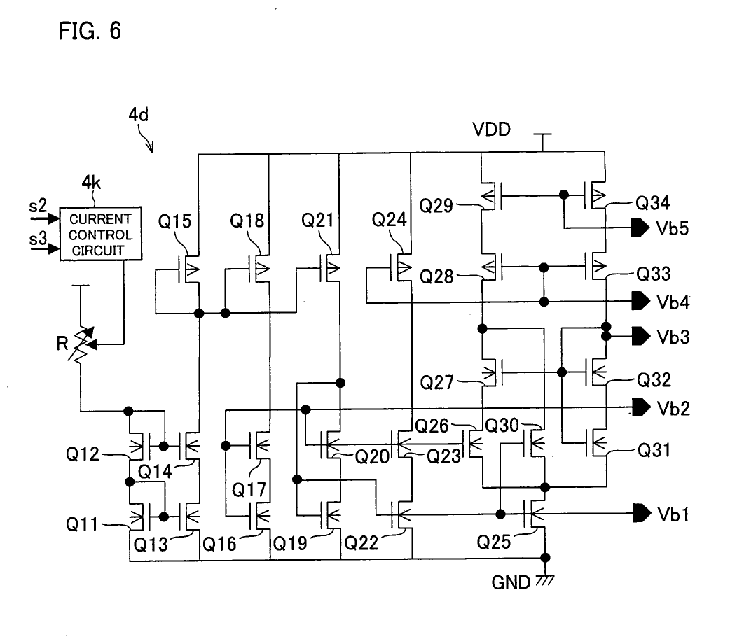

Next, FIG. 6 illustrates one example of the structure of the bias voltage generating circuit 4d. The bias voltage generating circuit 4d includes a current control circuit 4k, a resistor R, and transistors Q11 through Q34. The transistors Q11 through Q11, Q16, Q17, Q19, Q20, Q22, Q23, Q25 through Q27, and Q30 through Q32 are N-channel type MOS transistors. The transistors Q15, Q18, Q21, Q24, Q28, Q29, Q33, and Q34 are P-channel type MOS transistors.

The resistor R pulls up a bias voltage control terminal BIAS of the bias voltage generating circuit 4d to a power source. By using a current flowing in such a resistor R, the bias voltages Vb1 through Vb5 are simultaneously changed. The transistor Q11 has a source connected to GND. The transistor Q11 has a drain connected to a source of the transistor Q12. The transistor Q12 has a drain connected to the bias voltage control terminal BIAS. The transistor Q13 has a source connected to GND. The transistor Q13 has a drain connected to a source of the transistor Q14. The transistor Q11 has gate and drain each connected to a gate of the transistor Q13. The transistor Q12 has a gate and the drain each connected to a gate of the transistor Q14. The transistor Q14 has a drain connected to a drain of the transistor Q15. The transistor Q15 has a source connected to the power source VDD.

The transistor Q16 has a source connected to GND. The transistor Q16 has a drain connected to a source of the transistor Q17. The transistor Q17 has a drain connected to a drain of the transistor Q18. The transistor Q18 has a source connected to the power source VDD.

The transistor Q19 has a source connected to GND. The transistor Q19 has a drain connected to a source of the transistor Q20. The transistor Q20 has a drain connected to a drain of the transistor Q21. The transistor Q21 has a source connected to the power source VDD.

The transistors Q15, Q18, and Q21 have gates connected to one another.

The transistor Q22 has a source connected to GND. The transistor Q22 has a drain connected to a source of the transistor Q23. The transistor Q23 has a drain connected to a drain of the transistor Q24. The transistor Q24 has a source connected to the power source VDD.

The transistor Q25 has a source connected to GND. A drain of the transistor Q25, and sources of the transistors Q26, Q30, and Q31 are connected to one another.

A gate of the transistor Q19, the drain of the transistor Q20, a gate of the transistor Q22, a gate of the transistor Q25, and a gate of the transistor Q30 are connected to one another. A node of them has a voltage, which is to be supplied as the bias voltage Vb1.

The transistors Q16, Q17, Q20, Q23, and Q26 have gates connected to one another. A node of them has a voltage, which is to be supplied as the bias voltage Vb2.

The transistor Q26 has a drain connected to a source of the transistor Q27. The transistors Q30, Q27, and Q28 have drains connected to one another. The transistor Q31 has a drain connected to a source of the transistor Q32. Gates of the transistors Q27, Q31, and Q32, a drain of the transistor Q32, and a source of the transistor Q33 are connected to one another, and a node of them has a voltage, which is to be supplied as the bias voltage Vb3.

The transistors Q24, Q28, and Q33 have gates connected to one another. A node of them has a voltage, which is to be supplied as the bias voltage Vb4.

The transistor Q28 has a source connected to a drain of the transistor Q29. The transistor Q29 has a source connected to the power source VDD. The transistor Q33 has a source connected to a drain of the transistor Q34. The transistor Q34 has a source connected to the power source VDD. The transistor Q29 has a gate connected to a gate of the transistor Q34, and a node of them has a voltage, which is to be supplied as the bias voltage Vb5.

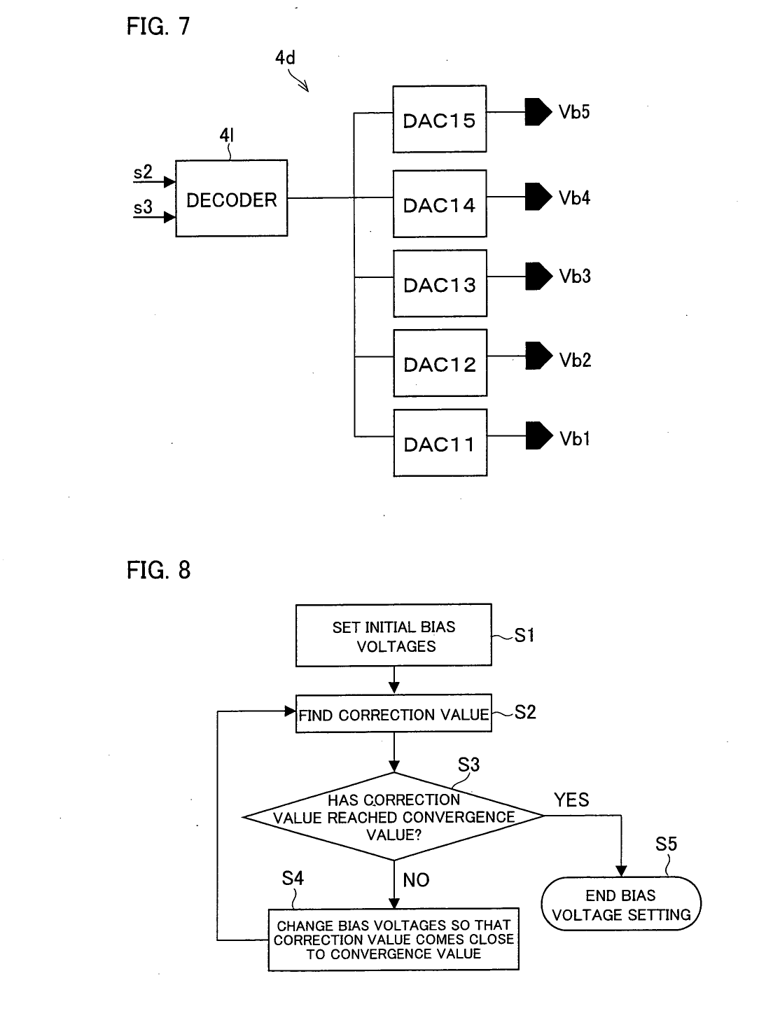

The bias voltage generating circuit 4d having such a structure is a circuit that simultaneously obtains the plurality of analog outputs, i.e., the bias voltages Vb1 through Vb5 in accordance with the analog input, i.e., the current flowing in the resistor R. A value of a current flowing into the resistor R is determined in accordance with the control signal s2 sent from the digital control circuit. Further, the bias voltage generating circuit 4d is arranged such that the value of the current can be arbitrarily determined in accordance with a control signal s3 sent from outside. The bias voltage generating circuit 4d may be constituted by D/A converting circuits as shown in FIG. 7.

Such a bias voltage generating circuit 4d shown in FIG. 7 is arranged such that: a decoder 41 converts the control signal s2 into a digital control signal suitable for the D/A converting circuits, and the digital control signal is converted into the bias voltages Vb by the D/A converters. By changing the digital signal supplied to the D/A converting circuits, the bias voltages to be generated can be changed. Therefore, the bias voltages can be controlled efficiently by using the digital signal obtained by processing the coefficient s1k that is supplied from the pipeline A/D converting circuit 4a and that has a digital value. The number of the D/A converters provided in the bias voltage generating circuit 4d may correspond to the number of the bias voltages Vb. For example, in cases where the amplifier of each of the stages uses five bias voltages Vb as shown in FIG. 5, D/A converters DAC11 through DAC15 respectively corresponding to the bias voltages Vb1 through Vb5 may be provided. The bias voltage generating circuit 4d uses the D/A converters so as to change the bias voltages Vb to be generated, individually. The number of the bias voltages Vb thus generated corresponds to the number of bias voltages used by the amplifier, so that the bias voltages Vb are generated efficiently.

Next, FIG. 8 illustrates a flow of setting the bias voltages Vb for each of the stages. In S1, initial bias voltages Vb are set, with the result that an initial value of a current to be supplied to the amplifier 4j is determined. In S2, the digital coefficient detection/control circuit 4b detects the coefficient s1k corresponding to the set bias voltages Vb and sent from the stage, i.e., the property of the multiply-by-2 amplifier circuit 4i of the pipeline A/D converting circuit 4a. A specific example of the property is the gain of the multiply-by-2 amplifying circuit 4i. The gain that the multiply-by-2 amplifying circuit 4i has as a result of the setting of the bias voltages Vb is referred to as “correction value”. A specific way of finding the gain of the multiply-by-2 amplifying circuit 4i will be described later. Carried out in S3 is to judge whether or not the correction value reaches a convergence value. In cases where the correction value is not judged to reach the convergence value, the control signal s2 is generated in S4 in accordance with the result of the detection of the coefficient s1k so as to change the bias voltages Vb such that the correction value comes close to the convergence value. As a result, the value of the current flowing into the amplifier 4j is changed, and the sequence goes back to S2. In S2, a correction value obtained as a result of setting such new bias voltages Vb is found, and the sequence goes to S3. In cases where the correction value reaches the convergence value, the sequence goes to S5, thereby ending the setting of the bias voltages Vb. By repeating such operations until the correction value reaches a predetermined convergence value, an unexpected error can be absorbed and optimum bias voltages Vb can be obtained.

Here, the following describes how it is judged whether or not the correction value has reached the convergence value. Consider a case where, e.g., the settling property initially corresponds to the curved line c1 shown in FIG. 13. In this case, there is a room for reducing the current flowing into the amplifier, so that the current is gradually reduced. While reducing the current gradually, judgment is carried out as to whether or not the curved line indicating the settling property coincides with the curved line c4 indicating that the output voltage Vout is settled to the predetermined voltage V1 at the predetermined time t1. In the case of each of the curved lines c1 through c4, the output voltage Vout is settled to the predetermined voltage V1 by no later than the predetermined time t1. However, when further reducing the current, the output voltage Vout does not reach the predetermined voltage V1 by no later than the predetermined time t1 as indicated by the curved line c5. In this case, the current flowing into the amplifier is increased again. When there is found a current, i.e., bias voltages allowing the settling property to correspond to the curved line c4, it is judged that the correction value has reached the convergence value.

Further, consider another case where, e.g., the settling property initially corresponds to the curved line c5 shown in FIG. 13, i.e., where the current flowing into the amplifier needs to be increased. Also in this case, it is judged whether or not the correction value has reached the convergence value, by judging whether or not the output voltage Vout corresponds to the curved line c4 indicating that the output voltage Vout is settled to the predetermined voltage V1 by no later than the predetermined time t1. The correction value keeps on changing while the settling property is changed from the curved line c5 to the curved line c4. However, the correction value is not supposed to change after the settling property goes beyond the curved line c3 (does not change while the settling property is changed from the curved line c5 to the curved line c3, c2, or c1). Therefore, when there is found a current, i.e., bias voltages allowing the settling property to correspond to the curved line c4, it is judged that the correction value has reached the convergence value.

As such, the steps in the flowchart of FIG. 8 are repeated such that the correction value is changed several times. This makes it possible to set the bias voltages Vb such that a minimally required current flows, with the result that current consumption can be reduced and restrained.

Note that: in cases where the coefficient indicating the property of the analog circuit provided in the A/D converting circuit is a value obtained by processing the digital value sent from the A/D converting circuit, the gain or gain error in the stage can be used as the property of the multiply-by 2 amplifying circuit 4i. In the structure shown in FIG. 4, the coefficient s1k may represent the gain or gain error; however, it is possible to find a coefficient indicating the gain or gain error, by processing the coefficient s1k. The processing of the coefficient s1k is carried out by the digital coefficient detection/control section 4b. In cases where the gain is used as the coefficient that the digital coefficient detection/control circuit 4b finally recognizes as the property of the multiply-by-2 amplifying circuit 4i, it is appropriate to set the convergence value at 2 or a value very close to 2. In cases where the coefficient is the gain error, it is appropriate to set the convergence value at 0. A circuit for finding the gain or gain error is provided anyway, for the sake of correction, in a structure for correcting an A/D conversion result Dk such as the A/D converting circuit inclusion circuit 4. Thus, in the A/D converting circuit inclusion circuit 4, such a circuit for finding the gain or gain error is provided in the digital coefficient detection/control circuit 4b. Therefore, no new circuit for generating the coefficient indicating the gain or gain error is required. Note that: in a pipeline A/D converting circuit, a gain is likely to be set at a value other than 2 (e.g., 4 or 8) in accordance with the number of digital outputs from each stage. However, even in such a case, the present invention is applicable.

Note that: the description herein assumes that the gain or gain error represents the coefficient (correction value) that the digital coefficient detection/control circuit 4b finally recognizes as the property of the multiply-by-2 amplifying circuit 4i; however, the present invention is not limited to this. The coefficient may be a gain index or a gain error index, each including (i) a function of the gain or gain error, or (ii) a calculation result thereof.

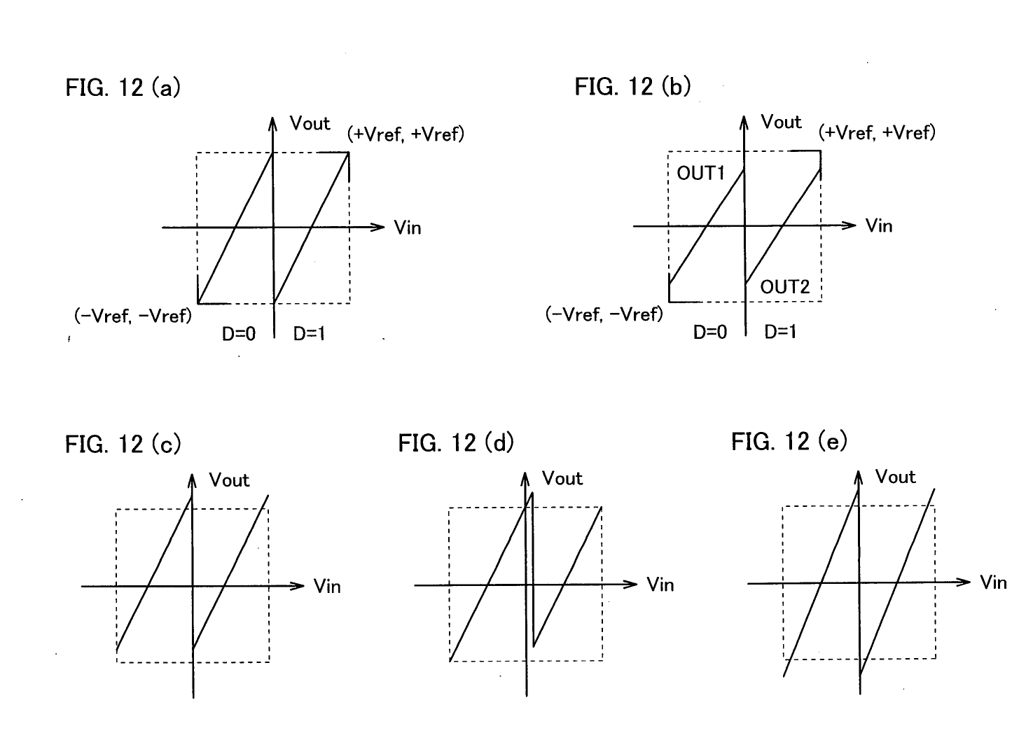

An example of a way of finding the gain of the multiply-by-2 amplifying circuit 4i of each stage is fully described in Non-patent citation 2, so that the following merely explains outlines thereof with reference to FIG. 4 and FIG. 12(a) through FIG. 12(e). Think that: the amplifier of the k-th stage (STAGE K) has an input/output property shown in FIG. 12(b), the analog input value Vres(k-1) is 0, and the sub A/D converter in the stage is externally forced to have a digital value D of 0 or 1. When the digital value D is 0, the analog output value Vres(k) corresponds to OUT1 shown in FIG. 12(b). On the other hand, when the digital value D is 1, the analog output value Vres(k) corresponds to OUT2 shown in FIG. 12(b). The gain of the multiply-by-2 amplifying circuit 4i corresponds to a value obtained by subtracting OUT2 from OUT1 (“OUT1−OUT2”). In an ideal case, the gain obtained is 2. However, actually, the gain is not more than 2 in the manufactured device. Meanwhile, Non-patent citation 3 teaches a calculation method for obtaining two types of gain by carrying out calculation similar to the subtraction “OUT1−OUT2” by using not only 0 but also two types of value for the analog input value. The coefficient s1k may be sent to the digital coefficient detection/control circuit 4b as the value obtained by the subtraction “OUT1−OUT2”. Alternatively, coefficients respectively indicating OUT 1 and OUT 2 are sequentially sent to the digital coefficient detection/control circuit 4b and the subtraction “OUT 1−OUT2” is carried out by the digital coefficient detection/control circuit 4b.

Further, consider a case of changing a current to be supplied to the multiply-by-2 amplifying circuit 4i of each stage of the pipeline A/D converting circuit 4a, in an application in which conversion speed is changeable. For example, for reducing a current such that the pipeline A/D converting circuit 4a operates slowly, the bias voltage setting signal s3 is supplied to the digital coefficient detection/control circuit 4b as shown in FIG. 4, with the result that the digital coefficient detection/control circuit 4b operates for setting of new bias voltages Vb in accordance with the convergence processing flow shown in FIG. 8. In this way, a current flowing into each amplifier is adjusted. In this case, the bias voltage setting signal s3 is also supplied to the bias voltage generating circuit 4d so as to bring the bias voltage generating circuit 4d into an operation state. This makes it possible to set (i) an optimum current in a case where the output voltage Vout needs to reach the predetermined voltage V1 by no later than the predetermined time t1, and (ii) an optimum current in a case where the output voltage Vout needs to reach the predetermined voltage V1 by no later than the predetermined time t2. Further, only when the bias voltages Vb need to be set again, the digital coefficient detection/control circuit 4b and the bias voltage generating circuit 4d are brought into the operation state, so that electric power consumption can be reduced.

As described above, in the A/D converting circuit inclusion circuit 4, the bias voltages Vb to be supplied are changed until the property is converged in a required correction value, so that the amplifier is always fed with optimum bias voltages Vb.

In the structure shown in FIG. 4, the adjustment of the operation condition of the multiply-by-2 amplifying circuit 4i, which is an analog circuit, makes it possible to control the pipeline A/D converting circuit 4a so as to reduce electric power consumption in the multiply-by-2 amplifying circuit 4i as much as possible while keeping the predetermined property to be a desired property so as not to, e.g., affect a value of a digital output Dout corresponding to an input voltage Vin supplied to the pipeline A/D converting circuit 4a. Therefore, even though the multiply-by-2 amplifying circuits 4i have manufacturing variation in their properties, it is possible to carry out electric power consumption reduction in accordance with the property of each manufactured multiply-by-2 amplifying circuit 4i. Further, while manufacturing an amplifier 4j that is so designed in view of avoidance of too large a margin as to be provided together with a circuit that is capable of changing and setting a parameter of the amplifier 4j in order to handle (i) property variation caused upon the manufacturing and (ii) various use modes, it is impossible to estimate a property that the multiply-by-2 amplifying circuit 4i will have upon completion of the manufacturing. Therefore, it is difficult to carry out appropriate parameter setting after the manufacturing. However, according to the structure shown in FIG. 4, the property of the manufactured multiply-by-2 amplifying circuit 4i is detected automatically or in response to an instruction made upon required, so that the manufactured multiply-by-2 amplifying circuit 4i does not have a margin more than necessary and can be used with good precision.

As such, according to the structure shown in FIG. 3, the multiply-by-2 amplifying circuit 4i having manufacturing variation in the predetermined property can be controlled by (i) finding the coefficient that indicates the predetermined property of the multiply-by-2 amplifying circuit 4i and that indicates the operation condition including the condition outside the multiply-by-2 amplifying circuit 4i, and (ii) adjusting the operation condition of the multiply-by-2 amplifying circuit 4i in accordance with the property and the operation condition including the condition outside the multiply-by-2 amplifying circuit 4i. This allows for (i) precision improvement whose realization is difficult only by carrying out parameter setting of the amplifier 4j, and (ii) reduction of current consumption. With this, it is possible to use the manufactured multiply-by-2 amplifying circuit 4i with good precision, and to realize such an A/D converting circuit inclusion circuit (electronic circuit device) that allows reduction of power consumption and circuit scale of the amplifier 4j.

Further, the A/D converting circuit in the structure shown in FIG. 4 is a pipeline A/D converting circuit including a plurality of stages, and is excellent in balance of conversion speed, conversion precision, and current consumption. Therefore, in cases where the operation condition of the multiply-by-2 amplifying circuit 4i of such a pipeline A/D converting circuit is adjusted in accordance with (i) the detected predetermined property of the multiply-by-2 amplifying circuit 4i and (ii) the detected condition outside the multiply-by-2 amplifying circuit 4i, the output of the multiply-by-2 amplifying circuit 4i is good in quality to some extent even before correction. This reduces load to be imposed on the digital correction circuit 4c.

In the meanwhile, the digital coefficient detection/control circuit 4b in the structure shown in FIG. 4 is a circuit that carries out digital processing with respect to the coefficient s1k. Moreover, the digital coefficient detection/control circuit 4b generates the control signal s2 in accordance with the detection result of the coefficient s1k through digital processing, and outputs the control signal s2 thus generated. In the meanwhile, the digital correcting circuit 4c corrects digital outputs D1 through DN supplied from the pipeline A/D converting circuit 4a, in accordance with the coefficient s1k. Then, the digital correcting circuit 4c outputs a digital output Dout′ obtained as a result of the correction. Since an A/D converting circuit such as the pipeline A/D converting circuit 4a generally outputs a digital value, it is possible to most efficiently process the digital output value of the A/D converting circuit in cases where a circuit for processing the output of the A/D converting circuit is a digital circuit. In this case, no additional analog circuit needs to be provided.

Note that each of the stages except the final stage in the pipeline A/D converting circuit 4a is provided with the multiply-by-2 amplifying circuit 4i serving as an analog circuit; however, the property detection and the operation condition adjustment may be carried out with respect to either all of the stages or some of the stages.

### Embodiment 2

FIG. 9 illustrates a structure of an A/D converting circuit inclusion circuit (electronic circuit device) 5 according to the present embodiment. The A/D converting circuit inclusion circuit 5 constitute a correction type A/D converting circuit, and includes bias voltage generating circuits 4d respectively corresponding to the first stage through the (N−1)-th stage of a pipeline A/D converting circuit. Each of the bias voltage generating circuits 4d is identical to the bias voltage generating circuit 4d (see FIG. 4) described in Embodiment 1. This makes it possible to set optimum bias voltages Vb in each of the stages. Hereinafter, the bias voltage generating circuits 4d are described as “bias voltage generating circuits 5dk” (k=1 to N−1).

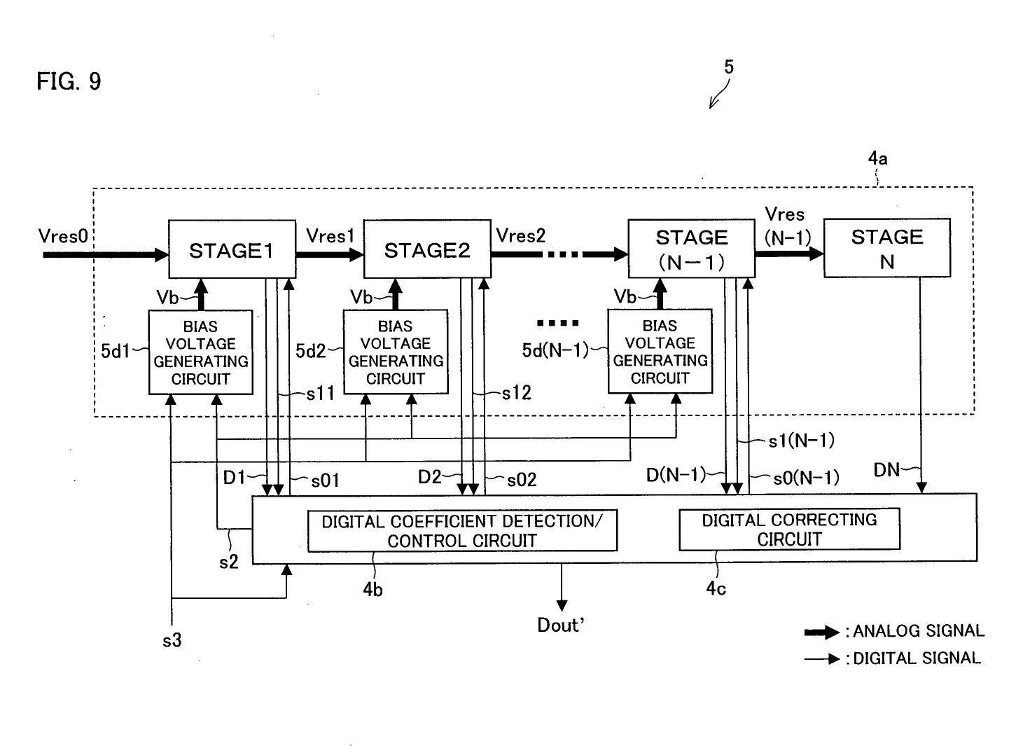

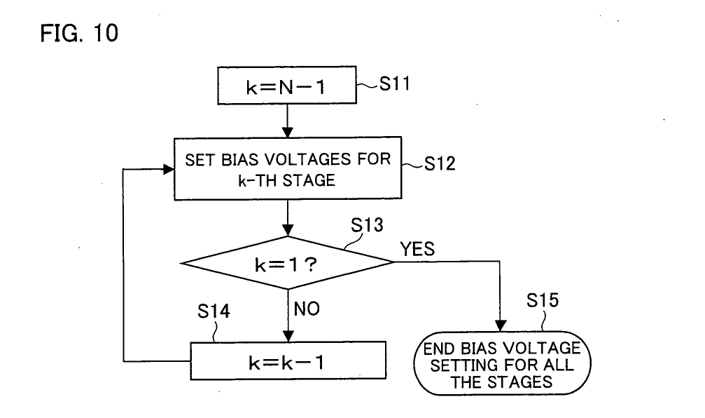

The bias voltages for the stages may be controlled to be individually set in a random order by the bias voltage generating circuits respectively provided to correspond to the first stage to the (N−1)-th stage. However, it is efficient to set the bias voltages in accordance with a flowchart illustrated in FIG. 10.

In a general correction type A/D converting circuit, a coefficient of the (N−1)-th stage is found by using a digital output of the N-th stage, and a coefficient of the (N−2)-th stage is found by using respective digital outputs of (i) the (N−1)-th stage whose coefficient has been determined and (ii) the N-th stage. As such, the coefficients are sequentially found in an order from a latter stage to an earlier stage. Correction is carried out in the same manner, so that setting of the bias voltages are carried out in the same manner. See FIG. 10. For optimization of an overall current value in the pipeline A/D converting circuit made up of the plurality of stages, k=N−1 is set in S11 and bias voltages Vb for the k-th stage, i.e., the (N−1)-th stage are set in S12 with the use of a correction value of the (N−1)-th stage in order to determine a current value of the (N−1)-th stage. The way of setting the bias voltages for each stage is fully explained in the above description. Next, in S13, it is judged whether or not k is 1. If k is not 1, the sequence goes to S14 and k=k−1 is set. Thereafter, the sequence goes back to S12. In S12, bias voltages Vb for the k-th stage, i.e., the (N−2)-th stage are set with the use of a correction value of the (N−2)-th stage in order to determine a current value of the (N−2)-th stage. On this occasion, the coefficient of the (N−2)-th stage is found by using the digital output of the (N−1)-th stage whose bias voltages have been determined and which is carrying out a pipeline operation. In this way, the bias voltages for the stages are set in the order from a latter stage to an earlier stage. When k=1 is satisfied in S13, the bias voltages Vb have been set for all the stages, thereby allowing optimization of the current values in the stages up to the earliest one, i.e., the first stage. Then, the sequence goes to S15, thus ending the setting of the bias voltages for all the stages. This allows the pipeline A/D converting circuit 4a to operate with an optimum current value.

Further, in the case where the bias voltage generating circuits are respectively provided to correspond to the stages that are provided in the pipeline A/D converting circuit 4a and that have amplifiers, the bias voltage generating circuits may be arranged so as to receive bias setting signals s3, individually. With this, bias voltages can be set, upon requested, only for a stage that needs bias voltage setting.

As described above, according to the present embodiment, the bias voltage generating circuits are respectively provided to correspond to the stages, each of which is provided in the pipeline A/D converting circuit 4a and each of which includes the multiply-by-2 amplifying circuit 4i. This makes it possible to set, upon requested, bias voltages Vb only for a stage that needs bias voltage setting.

Further, the bias voltages Vb are sequentially set in the order from a latter stage to an earlier stage of the pipeline A/D converting circuit 4a, so that optimum bias voltages Vb can be set for each of the stages. Accordingly, each stage of the pipeline A/D converting circuit 4a can operate with an optimum current value.

Further, the bias voltages Vb are sequentially set in the order from the final stage to the first stage, each of which is provided in the pipeline A/D converting circuit 4a and each of which includes the multiply-by-2 amplifying circuit 4i. So, optimum bias voltages Vb can be set for each of the stages. Accordingly, the pipeline A/D converting circuit 4a can operate with an optimum current value.

Further, the bias voltage generating circuits respectively provided to correspond to the stages of the pipeline A/D converting circuit 4a are brought into operation states by the bias voltage setting signals s3, individually. Therefore, bias voltages Vb can be set only for a stage that needs bias voltage setting, upon requested by way of a bias voltage setting signal s3.

The above description deals with the embodiments of the present invention. Each of the electronic circuit devices described above may be an analog circuit, or a circuit made up of an analog circuit and a digital circuit. Examples of the electronic circuit device includes (i) a camera module serving as a device unit, and (ii) a mobile electronic device (such as a mobile phone) serving as a commercial product.

Further, in the electronic circuit device, the coefficient detecting circuit, the control circuit, and the correcting circuit may be packed together with the analog circuit and the A/D converting circuit into one package as an IC. However, the present invention is not limited to this. IC packages respectively including the above circuits may be connected to one another via pins.

Further, one control means may be provided for one analog circuit so as to control the analog circuit. Alternatively, one control means may be provided for a plurality of analog circuits so as to control the analog circuits. Alternatively, a plurality of control means may be provided for one analog circuit so as to control the analog circuit. Each of the analog circuits is a circuit whose predetermined property is to be detected.

In cases where there are a plurality of predetermined properties to be detected, the detecting means may detect the predetermined properties as a coefficient by carrying out calculation. This makes it possible to efficiently detect the predetermined properties.

Further, in cases where the detection of the coefficient and the control carried out by the control means are carried out autonomously in the IC, no instruction for signal processing needs to be supplied from outside of the IC.

### INDUSTRIAL APPLICABILITY

The present invention is suitably applicable to an electronic circuit device including an A/D converting circuit, especially to an electronic circuit device including a pipeline A/D converting circuit.

1-27. (canceled)

28. An electronic circuit device, comprising:
an analog circuit;
detecting means for detecting a predetermined property of the analog circuit; and
control means for adjusting electric power consumption in the analog circuit in accordance with a result of the detection carried out by the detecting means.

29. An electronic circuit device, comprising:
an analog circuit;
detecting means for detecting a predetermined property of the analog circuit; and
control means for adjusting current consumption in the analog circuit in accordance with a result of the detection carried out by the detecting means.

30. The electronic circuit device as set forth in claim 28 or 29, wherein:
the detecting means detects the predetermined property of the analog circuit as a coefficient.

31. The electronic circuit device as set forth in claim 30, wherein:
the detecting means detects a plurality of the predetermined properties as a coefficient by carrying out calculation.

32. The electronic circuit device as set forth in claim 31, wherein:
the coefficient is a digital signal, and
the detecting means is a circuit for carrying out digital processing.

33. The electronic circuit device as set forth in claim 30, wherein:
an operation condition of the analog circuit is adjusted by a digital signal, and
the control means is a circuit for: (i) carrying out digital processing so as to generate, in accordance with the result of the detection, the signal for adjusting the operation condition of the analog circuit, and (ii) outputting the signal.

34. The electronic circuit device as set forth in claim 33, wherein:
the detection of the coefficient and control carried out by the control means are autonomously carried out in an IC.

35. The electronic circuit device as set forth in claim 28 or 29, wherein:
the analog circuit includes an amplifier, and
the control means adjusts current consumption of the amplifier so as to adjust the current consumption of the analog circuit.

36. The electronic circuit device as set forth in claim 35, wherein:
the analog circuit includes a bias voltage generating circuit for generating a bias voltage to be supplied to the amplifier, and
the control means changes the bias voltage to be generated by the bias voltage generating circuit, so as to adjust the current consumption of the analog circuit.

37. The electronic circuit device as set forth in claim 36, wherein:
the bias voltage generating circuit changes, according to an input current, the bias voltage to be generated.

38. The electronic circuit device as set forth in claim 37, wherein:
the bias voltage generating circuit is a D/A converting circuit which changes, according to an input digital signal, the bias voltages to be generated.

39. The electronic circuit device as set forth in claim 36, wherein:
the bias voltage generating circuit is brought into an operation state by a bias voltage setting signal supplied from outside.

40. The electronic circuit device as set forth in claim 36, wherein:
in order to adjust the current consumption of the analog circuit, the control means repeatedly changes the bias voltage to be generated by the bias voltage generating circuit, until the coefficient reaches a convergence value set in advance.

41. The electronic circuit device as set forth in claim 28 or 29, further comprising:
correcting means for correcting, in accordance with the coefficient, an output result obtained according to an operation condition of the analog circuit.

42. The electronic circuit device as set forth in claim 28 or 29, wherein:
the analog circuit is an A/D converting circuit for converting an analog input signal into a digital value, and outputting the digital value.

43. The electronic circuit device as set forth in claim 42, further comprising:
correcting means for correcting, in accordance with the coefficient, the digital value obtained by the A/D conversion carried out by the A/D converting circuit.

44. The electronic circuit device as set forth in claim 43, wherein:
the A/D converting circuit is a pipeline A/D converting circuit.

45. The electronic circuit device as set forth in claim 44, wherein:
the coefficient is an index of a gain of an amplifier provided in each of stages of the A/D converting circuit, which stages are provided in a form of a pipeline.

46. The electronic circuit device as set forth in claim 44, further comprising:
bias voltage generating circuits, which generate bias voltages to be supplied to amplifiers of the pipeline A/D converting circuit, and which are provided so as to correspond to a plurality of stages of the pipeline A/D converting circuit respectively.

47. The electronic circuit device as set forth in claim 46, wherein:
the bias voltages are sequentially determined in an order from a latter stage to an earlier stage of the pipeline A/D converting circuit.

48. The electronic circuit device as set forth in claim 47, wherein:
the bias voltages are sequentially determined in an order from a final stage to a first stage of stages respectively including the amplifiers.

49. The electronic circuit device as set forth in claim 46, wherein:
each of the bias voltage generating circuits respectively corresponding to the stages of the pipeline A/D converting circuit is brought into an operation state by a bias voltage setting signal supplied from outside.
